(19) United States
(12) Patent Application Publication
(10) Pub. No.: US 2007/0114619 A1
(43) Pub. Date: May 24, 2007

(54) SIDEWALL MOSFETS WITH EMBEDDED STRAINED SOURCE/DRAIN

(75) Inventor: Huilong Zhu, Poughkeepsie, NY (US)

Correspondence Address: SCHMEISER, OLSEN & WATTS, 22 CENTURY HILL DRIVE, SUITE 302, LATHAM, NY, 12110, US

(73) Assignee: International Business Machines Corporation, Armonk, NY (US)

(21) Appl. No.: 11/164,379

(22) Filed: Nov. 21, 2005

(51) Int. Cl. H01L 29/94; H01L 29/76; H01L 31/00

(52) U.S. Cl. 257/411

(57) ABSTRACT

Structures and methods for forming the same. The semiconductor structure includes (a) a substrate having a top substrate surface; (b) a channel region on the top substrate surface; (c) a gate dielectric region on the top substrate surface; and (d) a gate electrode region on the top substrate surface. The channel region is electrically insulated from the gate electrode region by the gate dielectric region. The semiconductor structure also includes first and second source/drain regions on the substrate. The channel region is disposed between the first and second source/drain regions. The channel region and the gate dielectric region are in direct physical contact with each other via an interfacing surface, which is essentially perpendicular to the top substrate surface. Each of the first and second source/drain regions comprises a crystal material that has a different lattice constant or spacing than that in the channel area.

### BACKGROUND OF THE INVENTION

1. Technical Field

The present invention relates to semiconductor transistors, and more specifically, to semiconductor transistors having embedded strained source/drain regions.

2. Related Art

The mobility of holes and electrons created in doped regions (e.g., channel and source/drain regions) of a transistor affects the switching speed of that transistor. Higher mobility of holes and electrons will result in higher switching speed for the transistor. Therefore, there is a need for a semiconductor transistor structure (and a method for forming the same) that has a high mobility for electrons and holes created in doped regions of the transistor.

### SUMMARY OF THE INVENTION

The present invention provides a semiconductor structure, comprising (a) a substrate having a top substrate surface; (b) a channel region on the top substrate surface; (c) a gate dielectric region on the top substrate surface; (d) a gate electrode region on the top substrate surface, wherein the channel region is electrically insulated from the gate electrode region by the gate dielectric region; and (e) first and second source/drain regions on the top substrate surface, wherein the channel region is disposed between the first and second source/drain regions, wherein the channel region and the gate dielectric region are in direct physical contact with each other via an interfacing surface which is essentially perpendicular to the top substrate surface, wherein each of the first and second source/drain regions comprises both first and second semiconductor materials, and wherein the first and second semiconductor materials are different from each other.

The present invention also provides a semiconductor structure, comprising (a) a substrate having a top substrate surface; (b) a channel region on the top substrate surface; (c) a gate dielectric region on the top substrate surface; (d) a gate electrode region on the top substrate surface, wherein the channel region is electrically insulated from the gate electrode region by the gate dielectric region; and (e) first and second source/drain regions on the top substrate surface, wherein the channel region is disposed between the first and second source/drain regions, wherein the channel region and the gate dielectric region are in direct physical contact with each other via an interfacing surface which is essentially perpendicular to the top substrate surface, wherein each of the first and second source/drain regions comprises both first and second semiconductor materials, wherein the first and second semiconductor materials are different from each other, wherein the first and second source/drain regions comprise first and second surfaces, respectively, wherein the first and second surfaces are essentially aligned with the interfacing surface between the channel region and the gate dielectric region, and wherein each of the first and second source/drain regions comprises a mixture of Si and Ge atoms.

The present invention also provides a semiconductor structure fabrication method, comprising providing a structure which includes (a) a substrate having a top substrate surface, (b) a semiconductor region on the top substrate surface, the semiconductor region comprising a channel region, (c) a gate dielectric region on the substrate, wherein the channel region and the gate dielectric region are in direct physical contact with each other via an interfacing surface which is essentially perpendicular to the top substrate surface, and (d) a gate electrode region on the top substrate surface, wherein the channel region is electrically insulated from the gate electrode region by the gate dielectric region; and replacing first and second portions of the semiconductor region with third and fourth portions, respectively, wherein each of the third and fourth portions comprises dopants and a mixture of first and second semiconductor materials, wherein the channel region is disposed between the first and second portions, and wherein the first and second semiconductor materials are different from each other.

The present invention provides a structure (and a method for forming the same) in which, the mobility of electron and hole is enhanced.

### BRIEF DESCRIPTION OF THE DRAWINGS

FIGS. 1-16D show the fabrication process for forming a structure, in accordance with embodiments of the present invention.

### DETAILED DESCRIPTION OF THE INVENTION

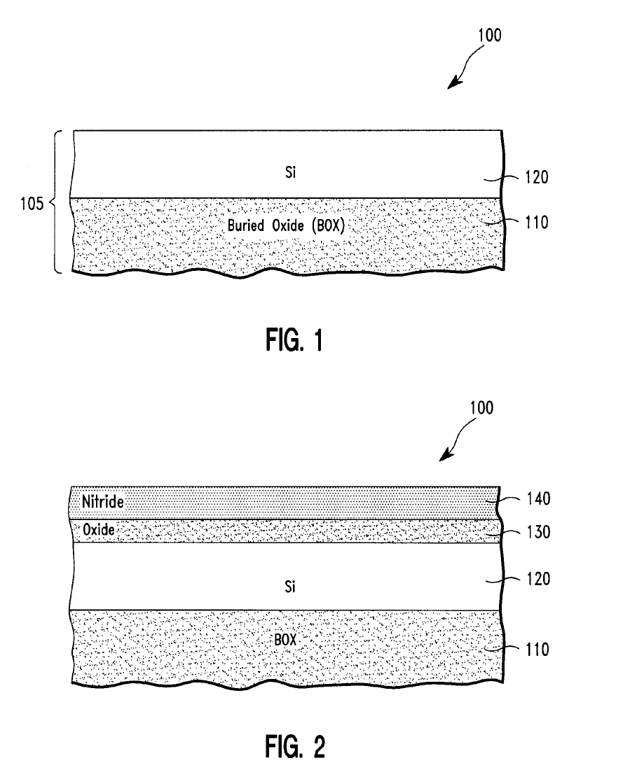

FIGS. 1-16D show the fabrication process for forming a structure 100, in accordance with embodiments of the present invention.

With reference to FIG. 1 (cross-section view), in one embodiment, the fabrication process starts out with an SOI (silicon on insulator) substrate 105 comprising (i) a buried oxide (BOX) layer 110, and (ii) a silicon layer 120 on the BOX layer 110. In an alternative embodiment, the fabrication process can start out with a bulk silicon wafer (not shown) instead of with the SOI substrate 105.

Next, with reference to FIG. 2 (cross-section view), in one embodiment, an oxide layer 130 is formed on top of the silicon layer 120. Illustratively, the oxide layer 130 comprises an oxide material such as silicon dioxide. In one embodiment, the silicon dioxide layer 130 is formed by chemical vapor deposition (CVD) of SiO2 on top of the SOI substrate 105.

Next, in one embodiment, a nitride layer 140 is formed on top of the oxide layer 130. Illustratively, the nitride layer 140 is formed by CVD.

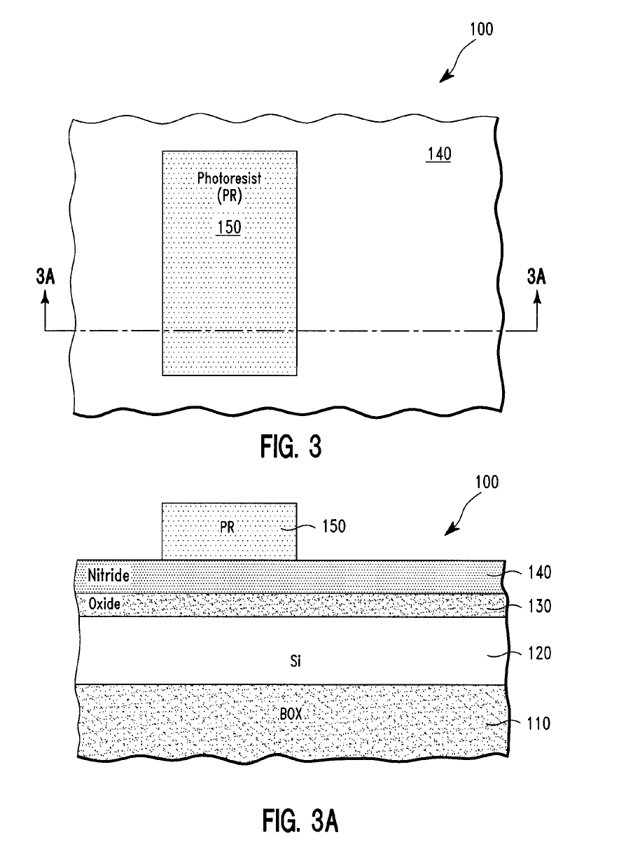

Next, with reference to FIG. 3 (top-down view), in one embodiment, a patterned photoresist layer 150 is formed on top of the nitride layer 140. Illustratively, the patterned photoresist layer 150 is formed by a conventional lithographic process. FIG. 3A shows a cross-section view of the structure 100 of FIG. 3 along a line 3A-3A.

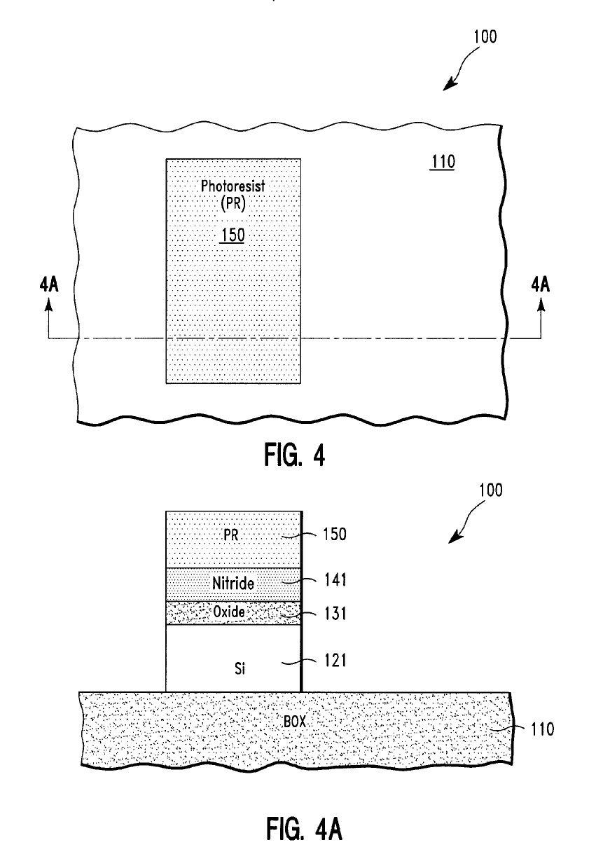

Next, in one embodiment, the patterned photoresist layer 150 is used as a blocking mask to etch the nitride layer 140, the oxide layer 130, and the silicon layer 120 in that order, stopping at the BOX layer 110, resulting in the structure 100 of FIG. 4 (top-down view). FIG. 4A shows a cross-section view of the structure 100 of FIG. 4 along a line 4A-4A. With reference to FIG. 4A, as a result of the etching, what remain of the nitride layer 140, the oxide layer 130, and the silicon layer 120 (FIG. 3A) are a nitride region 141, an oxide region 131, and a silicon region 121, respectively. In one embodiment, the etching of the nitride layer 140, the oxide layer 130, and the silicon layer 120 (FIG. 3A) is anisostropic such as reactive ion etching (RIE).

Next, with reference to FIG. 4 (top-down view) and FIG. 4A (cross-section view), in one embodiment, the patterned photoresist layer 150 is removed using wet etching.

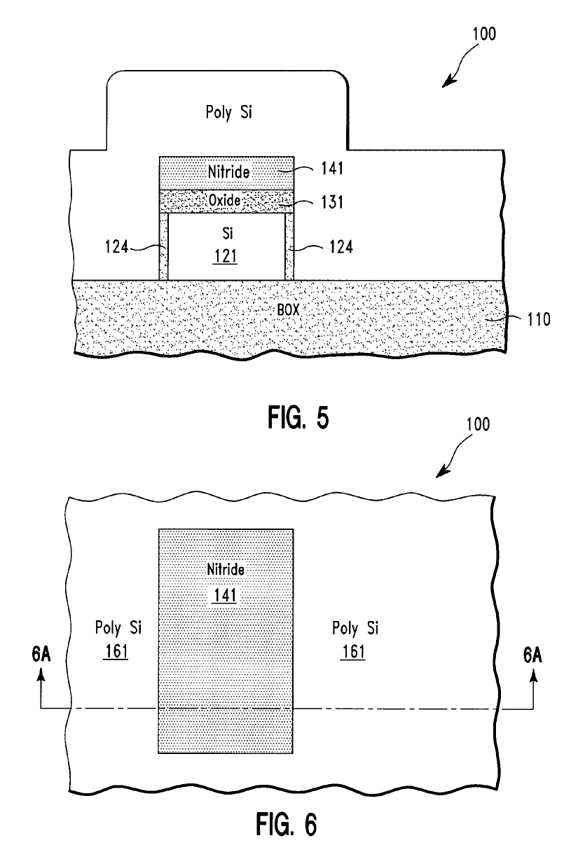

Next, with reference to FIG. 5 (cross-section view), in one embodiment, a dielectric region 124 is formed on side walls of the silicon region 121. Illustratively, the dielectric region 124 comprises an oxide material such as silicon dioxide. In one embodiment, the dielectric region 124 is formed by thermal oxidation.

Next, in one embodiment, a poly silicon layer 160 is formed on top the entire structure 100 right after the formation of the dielectric region 124. Illustratively, the poly silicon layer 160 is formed using CVD of poly silicon.

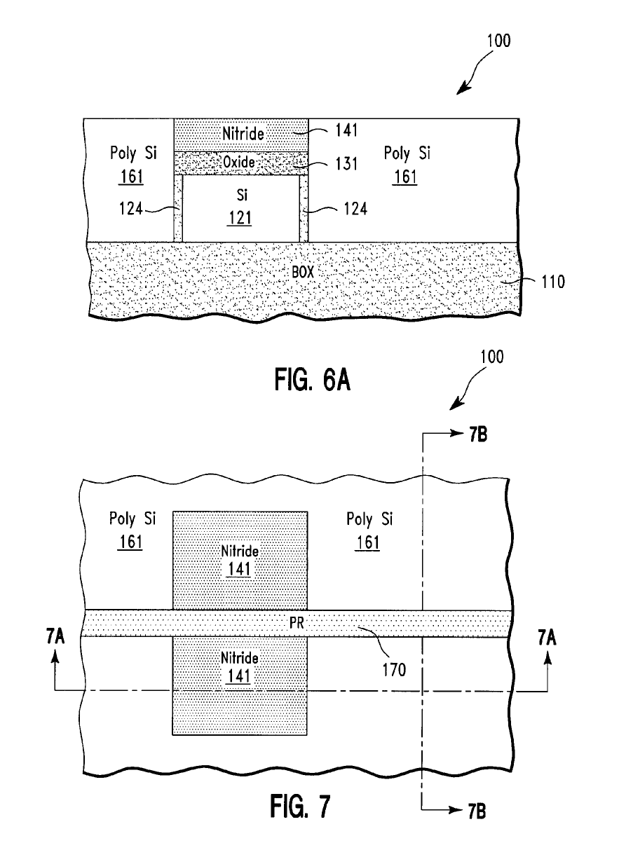

Next, in one embodiment, the poly silicon layer 160 is planarized using a chemical mechanical polishing (CMP) step, until the nitride region 141 is exposed to the surrounding ambient, resulting in the structure 100 of FIG. 6 (top-down view). What remains of the poly silicon layer 160 after the CMP step is a poly silicon region 161 (FIG. 6). FIG. 6A illustrates a cross-section view of the structure 100 of FIG. 6 along a line 6A-6A.

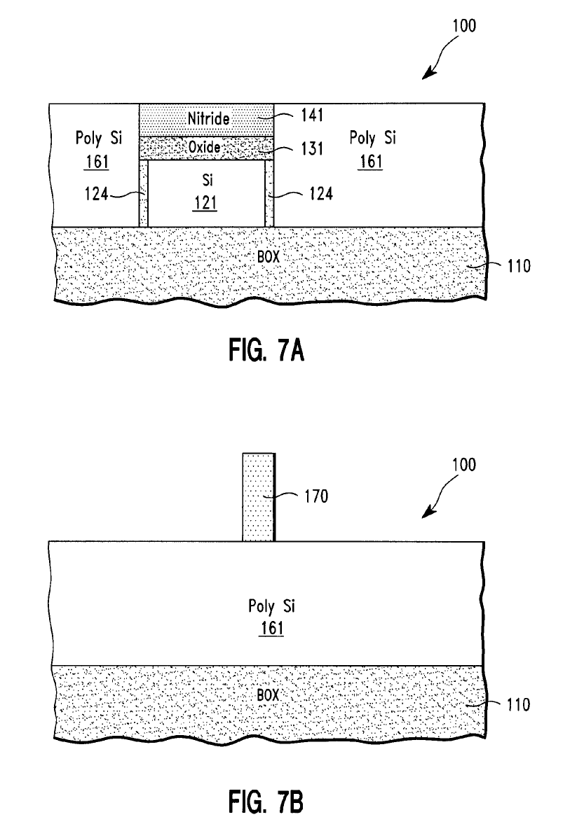

Next, with reference to FIG. 7 (top-down view), in one embodiment, a patterned photoresist layer 170 is formed on top of the nitride layer 141 and the poly silicon region 161. Illustratively, the patterned photoresist layer 170 is formed by a conventional lithographic process. FIGS. 7A-7B show cross-section views of the structure 100 of FIG. 7 along lines 7A-7A and 7B-7B, respectively.

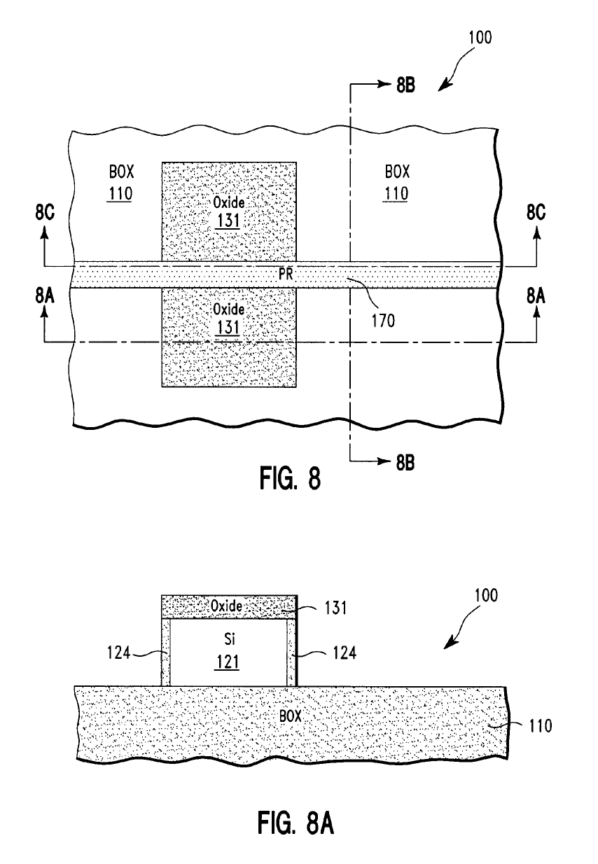

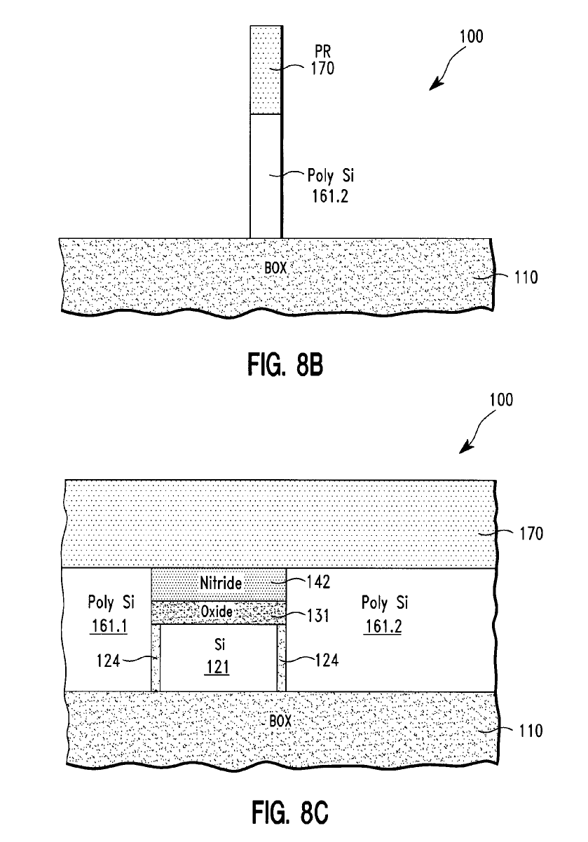

Next, in one embodiment, the patterned photoresist layer 170 is used as a blocking mask to directionally etch (a) the nitride region 141, stopping at the oxide layer 131 and (b) the poly silicon layer 161, stopping at the BOX layer 110, resulting in the structure 100 of FIG. 8 (top-down view). In one embodiment, the etching of the nitride region 141 and the poly silicon layer 161 is reactive ion etch (RIE). FIGS. 8A, 8B, and 8C show cross-section views of the structure 100 of FIG. 8 along lines 8A-8A, 8B-8B, and 8C-8C. As can be seen in FIG. 8C, what remain of the poly silicon layer 161 of FIG. 7 after the etching of the nitride region 141 and the poly silicon layer 161 of FIG. 7 are poly silicon regions 161.1 and 161.2. Also, what remains of the nitride region 141 of FIG. 7 is a nitride region 142.

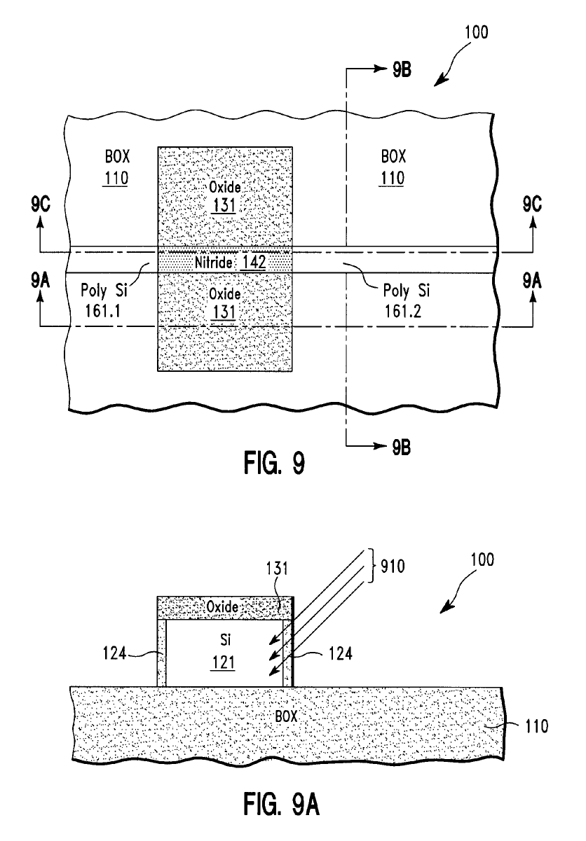

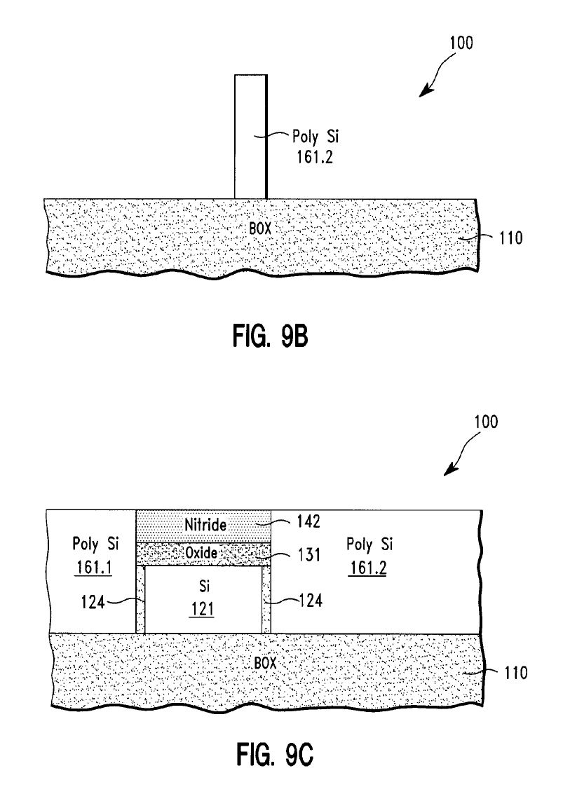

Next, in one embodiment, the patterned photoresist layer 170 is removed using dry and/or wet etching, resulting in the structure 100 of FIG. 9 (top-down view). FIGS. 9A, 9B, and 9C show cross-section views of the structure 100 of FIG. 9 along lines 9A-9A, 9B-9B, and 9C-9C.

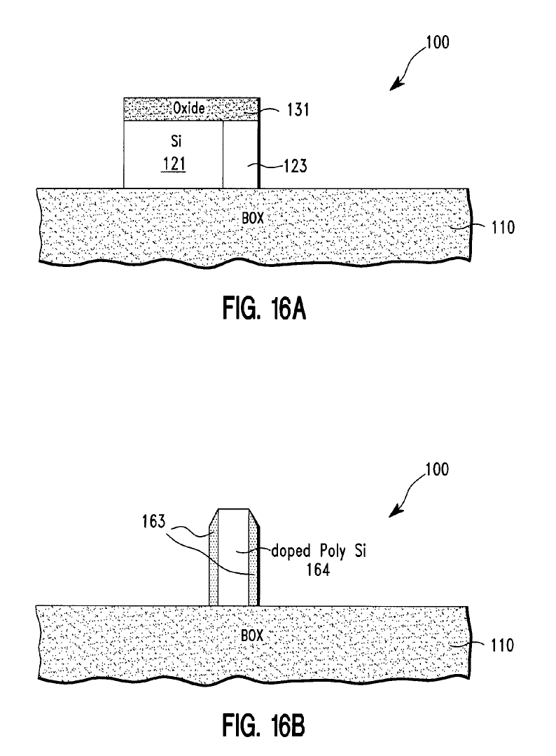

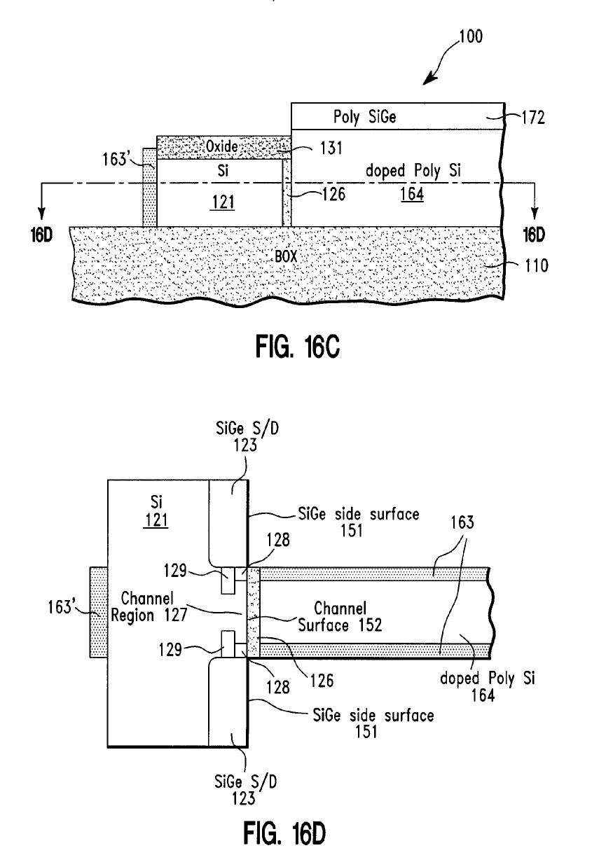

Next, with reference to FIG. 9A (cross-section view), in one embodiment, extension regions and halo regions (not shown, but can be seen in FIG. 16D as the halo regions 129 and extension regions 128) are formed in the silicon region 121 by ion-implantation whose directions of ion bombardment are indicated by the arrows 910. More specifically, in one embodiment, regarding extension ion-implantation, n-type dopants (As and P) are used for nMOSFETs (Metal-Oxide-Semiconductor Field Effect Transistors with n-type channel), whereas p-type dopants (B and In) are used for pMOSFETs (Metal-Oxide-Semiconductor Field Effect Transistors with p-type channel). In contrast, regarding halo ion-implantation, n-type dopants (As and P) are used for pMOSFETs, whereas p-type dopants (B and In) are used for nMOSFETs.

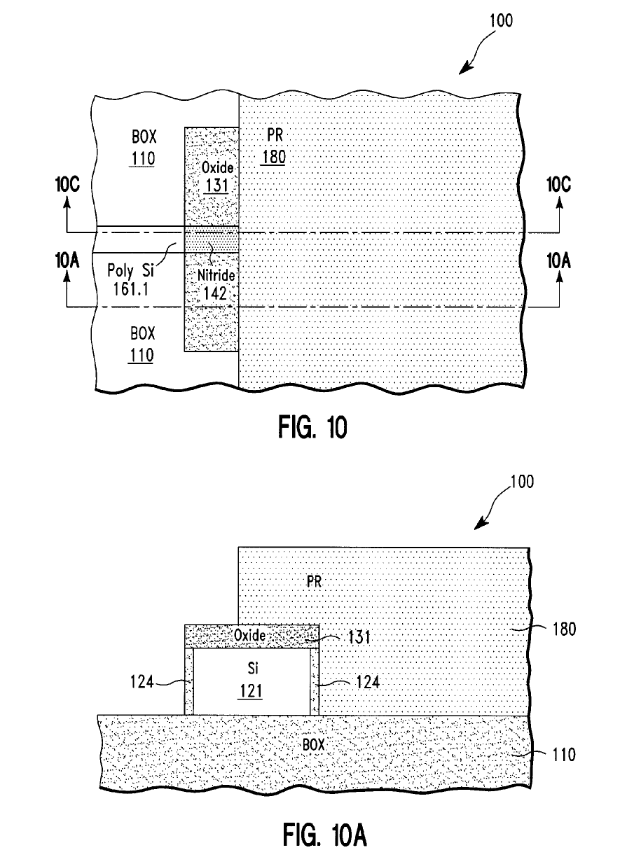

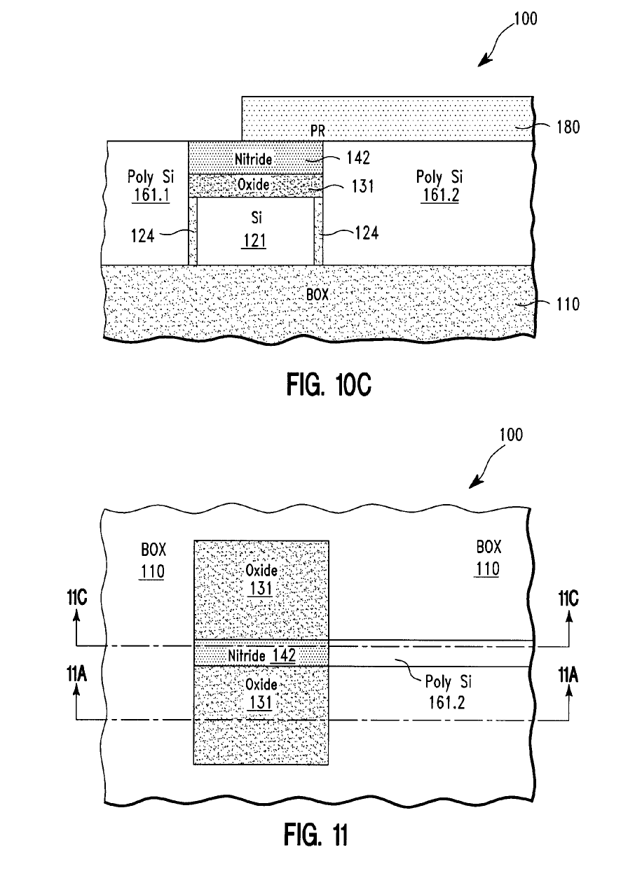

Next, with reference to FIG. 10 (top-down view), in one embodiment, a patterned photoresist layer 180 is formed on top of the structure 100 of FIG. 9 so as to cover the poly silicon region 161.2. Illustratively, the patterned photoresist layer 180 is formed by a conventional lithographic process. FIG. 10A shows a cross-section view of the structure 100 of FIG. 10 along a line 10A-10A whereas FIG. 10C shows a cross-section view of the structure 100 of FIG. 10 along a line 10C-10C.

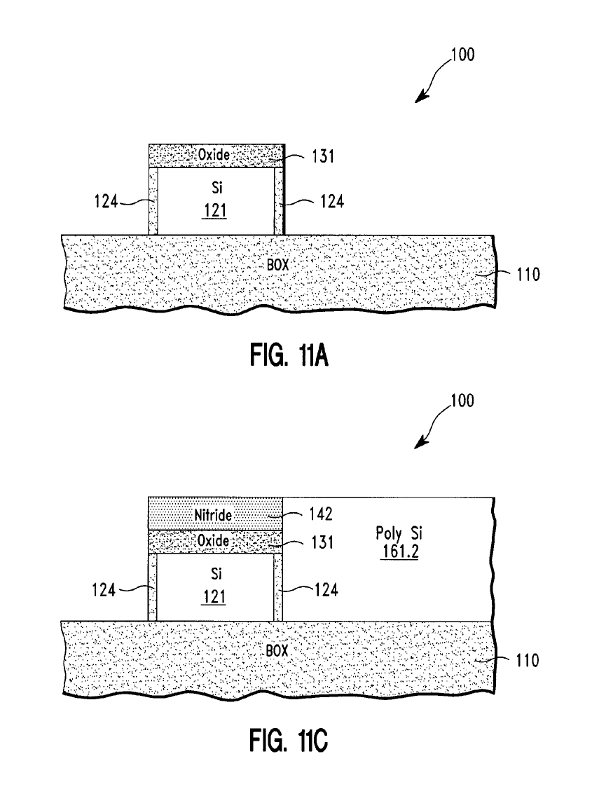

Next, in one embodiment, the patterned photoresist layer 180 is used as a blocking mask to etch the poly silicon region 161.1 so as to remove the poly silicon region 161.1. Next, in one embodiment, the patterned photoresist layer 180 is removed using wet etching, resulting in the structure 100 of FIG. 11 (top-down view). FIG. 11A shows a cross-section view of the structure 100 of FIG. 11 along a line 11A-11A whereas FIG. 11C shows a cross-section view of the structure 100 of FIG. 11 along a line 11C-11C.

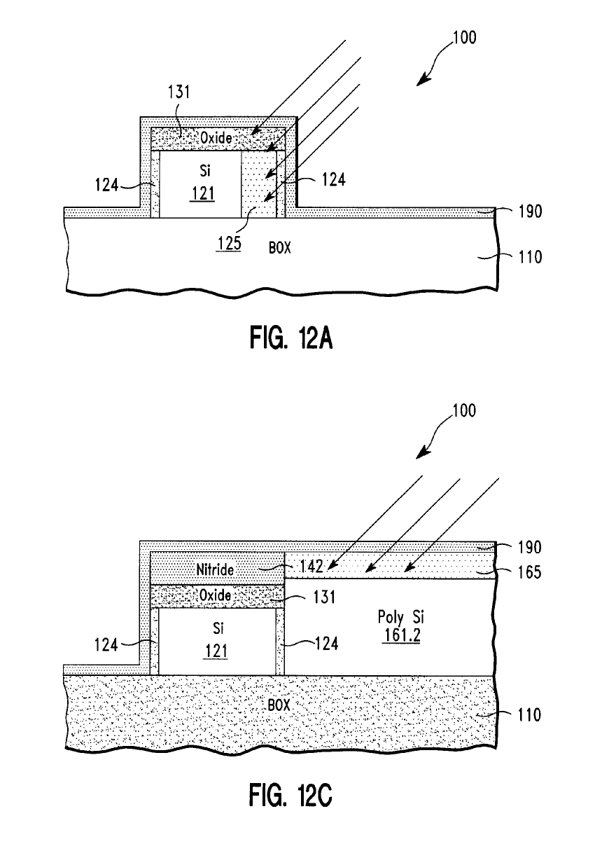

Next, with reference to FIG. 12A and FIG. 12C, in one embodiment, a nitride layer 190 is formed on top of the entire structure 100 of FIG. 11. It should be noted that FIG. 12A and FIG. 12C show cross-section views of the structure 100 of FIG. 11 along lines 11A-11A and 11C-11C after the nitride layer 190 is formed. Illustratively, the nitride layer 190 is formed by CVD or PECVD (Plasma-enhanced CVD).

Next, in one embodiment, Ge atoms are implanted in the silicon region 121 (FIG. 12A) and the poly silicon region 161.2 (FIG. 12C) by ion implantation so as to form two Ge-doped silicon regions 125 in the silicon region 121 (only one of which is shown in FIG. 12A) and a Ge-doped poly silicon region 165 (FIG. 12C).

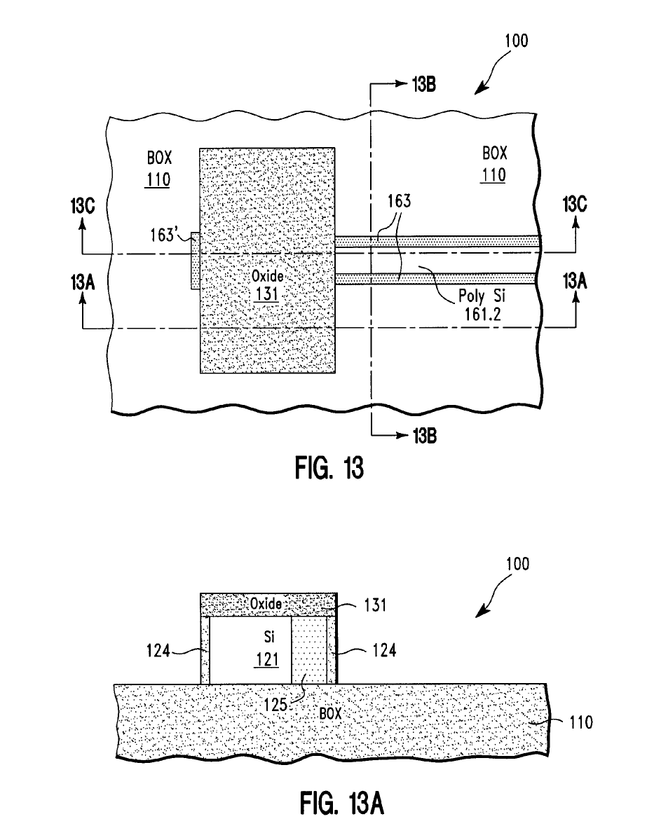

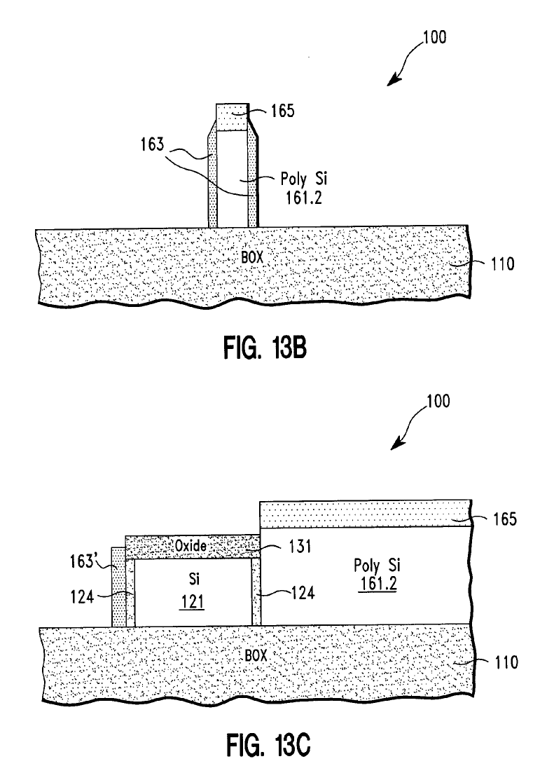

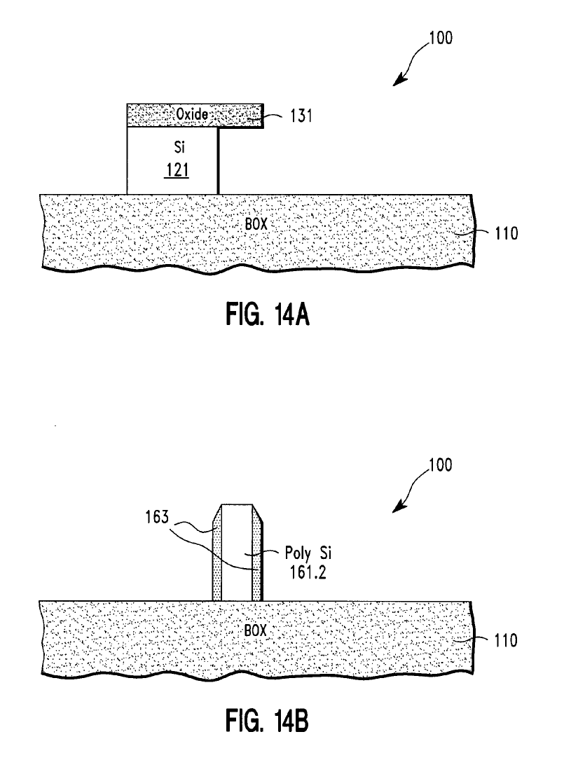

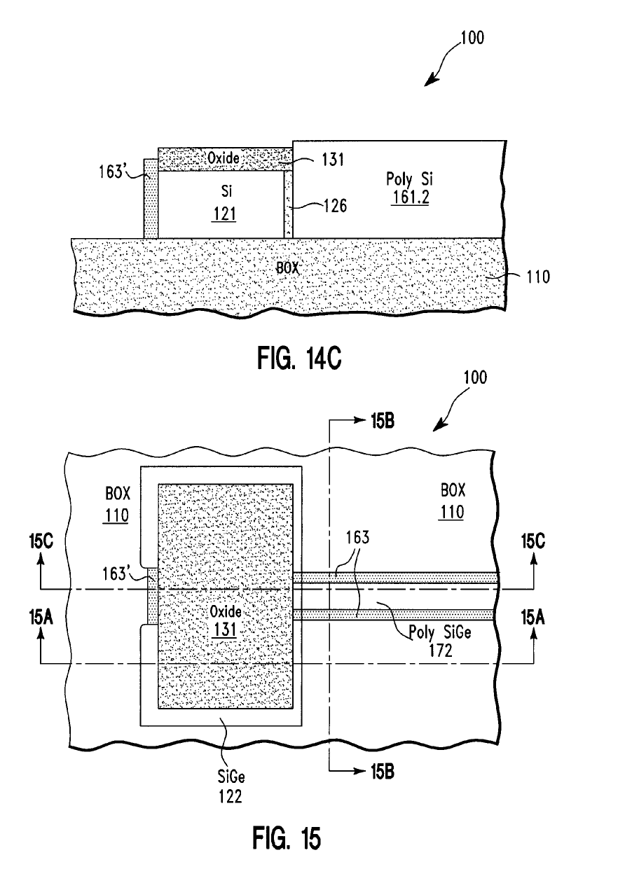

Next, in one embodiment, the nitride layer 190 is directionally etched (illustratively, by reactive ion etching, i.e., RIE etch) so as to form nitride spacers 163 (FIG. 13). It should be noted that, the etching of the nitride layer 190 does not stop until the nitride region 142 (FIG. 12C) and all portions of the nitride layer 190 on side walls of the silicon region 121 are completely removed, resulting in the structure 100 of FIG. 13. As the result of the etching of the nitride layer 190, what remain of the nitride layer 190 are the nitride spacers 163 (FIG. 13) on side walls of the poly silicon region 161.2 and a residual nitride spacer 163′(FIG. 13). FIGS. 13A, 13B, and 13C show cross-section views of the structure 100 of FIG. 13 along lines 13A-13A, 13B-13B, and 13C-13C.

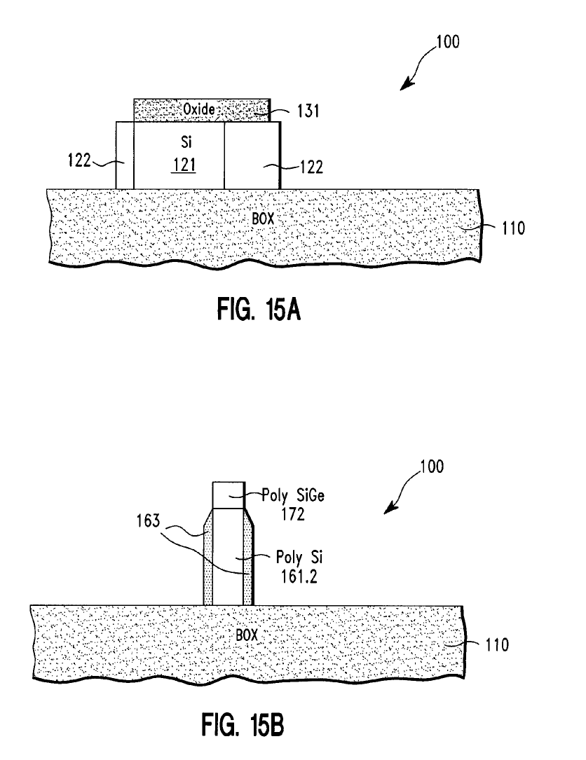

Next, with reference to FIG. 13A, in one embodiment, the dielectric region 124 is etched by wet etching. As the result of the etching of the dielectric region 124, what remains of the dielectric region 124 is a gate dielectric region 126 (FIG. 14C). Next, in one embodiment, after the etching of the dielectric region 124, the two Ge-doped silicon regions 125 and the Ge-doped poly silicon region 165 are removed by wet etching selective to Ge undoped Si (i.e., Si that is not doped with Ge). FIG. 14A shows the structure 100 of FIG. 13A after the dielectric region 124 is etched and the two Ge-doped silicon regions 125 are removed. FIG. 14B and FIG. 14C show the structure 100 of FIG. 13B and FIG. 13C, respectively after the Ge-doped poly silicon region 165 is removed.

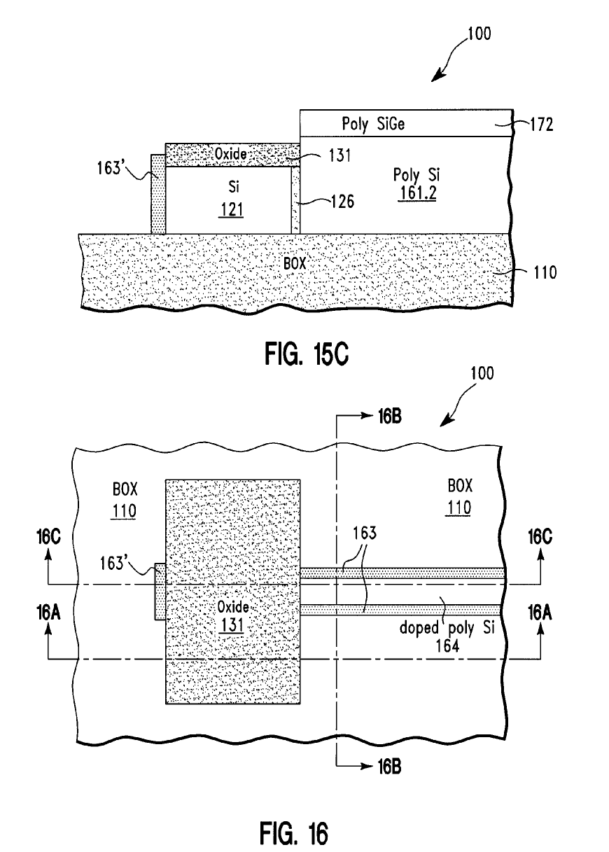

Next, with reference to FIGS. 14A-C, in one embodiment, a mixture of Si and Ge (or in short, SiGe) is epitaxially grown on the silicon region 121 and the poly silicon region 161.2, resulting in the structure 100 of FIG. 15. It should be noted that materials used in the above epitaxial growth step for pMOSFETs and nMOSFETs are SiGe and Si:C, respectively (wherein Si:C indicates a mixture of Si and C atoms). FIGS. 15A, 15B, and 15C show cross-section views of the structure 100 of FIG. 15 along lines 15A-15A, 15B-15B, and 15C-15C. As a result of the epitaxial growth of SiGe on the silicon region 121 and the poly silicon region 161.2, SiGe region 122 is formed on side walls of the silicon region 121 (FIG. 15A), and a poly SiGe region 172 is formed on top of the poly silicon region 161.2 (FIG. 15B and FIG. 15C).

In one embodiment, p-type dopants are added into the mixture of Si and Ge during the epitaxial growth so that the SiGe region 122 and the poly SiGe region 172 are doped with the p-type dopants.

Next, in one embodiment, the structure 100 of FIG. 15 is annealed so as to (i) activate the dopants in the SiGe region 122 and (ii) diffuse dopants implanted in the poly SiGe region 172 into the poly silicon region 161.2. As a result of the annealing step, the poly silicon region 161.2 becomes a doped poly silicon region 164 (FIG. 16).

Next, in one embodiment, the oxide region 131 is used as a blocking mask to directionally etch the SiGe region 122 stopping at the BOX layer 110, resulting in two SiGe source/drain (S/D) regions 123 (FIG. 16D). Illustratively, the SiGe region 122 is directionally etched using RIE etch selective to Si. Next, in one embodiment, the etching of the SiGe region 122 to create the two SiGe S/D regions 123 also removes the poly SiGe region 172, resulting in the structure 100 of FIG. 16. FIGS. 16A-C show cross-section views of the structure 100 of FIG. 16 along lines 16A-16A, 16B-16B, and 16C-16C. FIG. 16D shows a top-down view of the structure 100 of FIG. 16C along a line 16D-16D. As can be seen in FIG. 16D, as a result of the etching of the SiGe region 122 (FIG. 15), SiGe side surfaces 151 of the SiGe S/D regions 123 are essentially aligned with a channel surface 152.

In summary, with reference to FIG. 16D, the transistor structure 100 includes a channel region 127 disposed between the extension regions 128 and the halo regions 129. The channel region 127 is electrically insulated from the doped poly silicon region 164 by the gate dielectric region 126. The structure 100 also includes the first and second SiGe S/D regions 123. Because the S/D regions 123 comprise silicon and germanium atoms, there exists stress in the lattice of the first and second S/D regions 123 resulting in high mobility of electrons and holes created in the first and second S/D regions 123. As a result, the transistor structure 100 operates at a higher speed than in the prior art. In one embodiment, in the case the first and second S/D regions 123 comprise single crystal SiGe, the average lattice constant (or in short, lattice constant) of the single crystal SiGe is at least 0.2% larger than the lattice constant of single crystal Si in the channel region 127. In one embodiment, in the case the first and second S/D regions 123 comprise single crystal Si:C, the average lattice constant (or in short, lattice constant) of the single crystal SiGe is at least 0.2% smaller than the lattice constant of single crystal Si in the channel region 127.

While particular embodiments of the present invention have been described herein for purposes of illustration, many modifications and changes will become apparent to those skilled in the art. Accordingly, the appended claims are intended to encompass all such modifications and changes as fall within the true spirit and scope of this invention.

What is claimed is:

1. A semiconductor structure, comprising:
(a) a substrate having a top substrate surface;
(b) a channel region on the top substrate surface;
(c) a gate dielectric region on the top substrate surface;
(d) a gate electrode region on the top substrate surface,
wherein the channel region is electrically insulated from the gate electrode region by the gate dielectric region; and
(e) first and second source/drain regions on the top substrate surface,
wherein the channel region is disposed between the first and second source/drain regions,
wherein the channel region and the gate dielectric region are in direct physical contact with each other via an interfacing surface which is essentially perpendicular to the top substrate surface,
wherein each of the first and second source/drain regions comprises both first and second semiconductor materials, and
wherein the first and second semiconductor materials are different from each other.

2. The structure of claim 1, wherein the channel region comprises silicon.

3. The structure of claim 1, wherein the gate dielectric region comprises silicon dioxide.

4. The structure of claim 1, wherein the gate electrode region comprises doped poly silicon.

5. The structure of claim 1, wherein the first and second source/drain regions comprise first and second surfaces, respectively, and
wherein the first and second surfaces are essentially aligned with the interfacing surface between the channel region and the gate dielectric region.

6. The structure of claim 1, wherein each of the first and second source/drain regions comprises a mixture of Si and Ge atoms.

7. The structure of claim 6, wherein each of the first and second source/drain regions comprises p-type dopants.

8. The structure of claim 1, wherein each of the first and second source/drain regions comprises a single crystalline material having a lattice constant larger than that of a material of the channel region by at least 0.2%.

9. The structure of claim 1, wherein each of the first and second source/drain regions comprises a mixture of Si and Carbon atoms.

10. The structure of claim 9, wherein each of the first and second source/drain regions comprises n-type dopants.

11. The structure of claim 1, wherein each of the first and second source/drain regions comprises a crystalline material having a lattice constant smaller than that of a material of the channel region by at least 0.2%.

12. The structure of claim 1, further comprising nitride spacers on side walls of the gate electrode region.

13. A semiconductor structure, comprising:
(a) a substrate having a top substrate surface;
(b) a channel region on the top substrate surface;
(c) a gate dielectric region on the top substrate surface;
(d) a gate electrode region on the top substrate surface,
wherein the channel region is electrically insulated from the gate electrode region by the gate dielectric region; and
(e) first and second source/drain regions on the top substrate surface,
wherein the channel region is disposed between the first and second source/drain regions,
wherein the channel region and the gate dielectric region are in direct physical contact with each other via an interfacing surface which is essentially perpendicular to the top substrate surface,
wherein each of the first and second source/drain regions comprises both first and second semiconductor materials,
wherein the first and second semiconductor materials are different from each other,
wherein the first and second source/drain regions comprise first and second surfaces, respectively,
wherein the first and second surfaces are essentially aligned with the interfacing surface between the channel region and the gate dielectric region, and
wherein each of the first and second source/drain regions comprises a mixture of Si and Ge atoms.

14. The structure of claim 13, wherein each of the first and second source/drain regions further comprises p-type dopants.

15. The structure of claim 13, further comprising nitride spacers on side walls of the gate electrode region.

16.
providing a structure which includes (a) a substrate having a top substrate surface, (b) a semiconductor region on the top substrate surface, the semiconductor region comprising a channel region, (c) a gate dielectric region on the substrate, wherein the channel region and the gate dielectric region are in direct physical contact with each other via an interfacing surface which is essentially perpendicular to the top substrate surface, and (d) a gate electrode region on the top substrate surface, wherein the channel region is electrically insulated from the gate electrode region by the gate dielectric region; and
replacing first and second portions of the semiconductor region with third and fourth portions, respectively,
wherein each of the third and fourth portions comprises dopants and a mixture of first and second semiconductor materials,
wherein the channel region is disposed between the first and second portions, and
wherein the first and second semiconductor materials are different from each other.

17. The method of claim 16,
wherein the first and second semiconductor materials are Si and Ge, respectively, and
wherein the dopants are p-type.

18. The method of claim 16,
wherein the first and second semiconductor materials are Si and C, respectively, and
wherein the dopants are n-type.

19. The method of claim 16, wherein said replacing the first and second portions comprises:
implanting Ge dopants in the semiconductor region so as to form the first and second portions, wherein the first and second portions comprise the Ge dopants;
removing the first and second portions; and
depositing a mixture of Si and Ge in empty spaces of the removed first and second portions so as to form the third and fourth portions, respectively.

20. The method of claim 19, wherein the Ge dopants are implanted by ion-implantation.

21. The method of claim 16, wherein said replacing the first and second portions comprises;
implanting Ge dopants in the semiconductor region so as to form the first and second portions, wherein the first and second portions comprise the Ge dopants;
removing the first and second portions; and
depositing a mixture of Si and C in empty spaces of the removed first and second portions so as to form the third and fourth portions, respectively.

22. The method of claim 21, wherein said removing the first and second portions comprises etching the first and second portions by wet etching.
